(19) United States
(12) Patent Application Publication
(10) Pub. No.: US 2023/0381900 A1
(43) Pub. Date: Nov. 30, 2023

(54) MULTI-AXIS GRIPPER UNIT OF TURNTABLE TYPE PROBE PIN BONDING APPARATUS

(71) Applicant: LASERSSEL CO., LTD., Asan-si (KR)

(72) Inventors: Jae Joon CHOI, Gwangju-si (KR); Byung Roc KIM, Incheon (KR); Tae Kyu KIM, Hwaseong-si (KR); Dong Sik KIM, Goyang-si (KR); Jun Gi LEE, Cheonan-si (KR); Sang Won LEE, Asan-si (KR)

(21) Appl. No.: 17/976,028

(22) Filed: Oct. 28, 2022

(30) Foreign Application Priority Data
May 24, 2022 (KR) 10-2022-0063635

(51) Int. Cl. B23K 37/053; B23K 37/047; B23K 26/08; B23K 26/20

(52) U.S. Cl. CPC B23K 37/053; B23K 37/047; B23K 26/0853; B23K 26/20

(57) ABSTRACT

The present invention relates to a turntable-type probe pin laser bonding apparatus wherein a pin gripper mounted on four surfaces automatically laser-bonds a probe pin to a probe card while continuously rotating pin grippers in a turntable method. More particularly, the present invention relates to a multi-axis gripper unit of a turntable type probe pin laser bonding apparatus that can continuously process the pickup, dipping, and laser bonding of probe pins while freely moving linearly or rotationally in multi-axis directions, for example, the X-axis, Y-axis, Xθ-axis, Yθ-axis, and the gripper axis, with high precision in micrometer units by being applied to the laser bonding unit.

### CROSS-REFERENCE TO RELATED APPLICATION

This application is based on and claims priority to Korean Patent Application No. 10-2022-0063635 filed on May 24, 2022, with the Korean Intellectual Property Office, the disclosures of which are incorporated herein by reference in its entirety.

### TECHNICAL FIELD

The present invention relates to a turntable-type probe pin laser bonding apparatus wherein a pin gripper mounted on four surfaces automatically laser-bonds a probe pin to a probe card while continuously rotating pin grippers in a turntable method. More particularly, the present invention relates to a multi-axis gripper unit of a turntable type probe pin laser bonding apparatus that can continuously process the pickup, dipping, and laser bonding of probe pins while freely moving linearly or rotationally in multi-axis directions, for example, the X-axis, Y-axis, Xθ-axis, Yθ-axis, and the gripper axis, with high precision in micrometer units by being applied to the laser bonding unit.

### BACKGROUND ART

In general, a probe card is an apparatus for testing the electrical performance of a chip formed on a semiconductor substrate.

More specifically, an innumerable plurality of probe pins is bonded to the probe card. The plurality of probe pins contacts the semiconductor chip pad and applies an electrical signal to check whether the chip is normal.

As these semiconductor devices continue to be highly integrated, the circuit patterns of the semiconductor devices are also being miniaturized. Accordingly, there is also a demand for a probe card to which probe pins are bonded to have an interval corresponding to the interval of the microcircuit patterns of the semiconductor device.

However, since the conventional method of manufacturing a probe card is not fully automated, it takes a lot of time to manufacture one probe card, and the defect rate is also high.

More specifically, in the past, a person used a pincette to move and load probe pins on a wafer into a cassette. Since a person had to manually set the probe pin on the wafer vertically and then load it into the cassette, there was a problem in that the probe pin was scratched or bent, resulting in a defect.

In recent years, since the thickness of the probe pins is becoming finer to reduce the gap between the probe pins, the restoring force of the probe pins has been greatly reduced. That is, probe pins on the wafer are more likely to be easily damaged, even with a small impact in the process of being manually transferred to the cassette. Therefore, it is necessary to automate the transfer of the probe pin through a minimum force that does not damage the probe pin.

In addition, conventionally, when a person directly transfers a probe pin, the time for loading the probe pin on the wafer into the cassette is different depending on the technical skill level of each person. Even for a skilled person, it was difficult to accurately predict the production volume of semi-finished products over time because there was a difference in production per hour.

And conventionally, due to the thickness of the apparatus for transferring the probe pins, there was a limit in narrowing the gap between the probe pins attached to the probe card.

More specifically, since the grip module that grips and transports the probe pins on the probe card has a certain thickness, even though the thickness of the probe pins is made thin, there was a limit that the gap between the probe pins attached to the probe card could not be narrowed down to at least the thickness of the grip module.

Accordingly, at a probe card production site, there is a high demand for a probe pin bonding apparatus that can operate fully automatically, minimize the impact applied to the probe pin, and minimize the gap between the probe pins attached to the probe card.

Hereinafter, referring to FIGS. 1 and 2, the applicant of the present invention has previously filed a patent application for a turntable-type probe pin laser bonding apparatus that automatically laser bonds the probe pins to the probe card while the pin grippers mounted on each of the four sides, rotate continuously in a turntable method.

FIG. 1 is a plan view showing the configuration of a conventional turntable-type probe pin laser bonding apparatus according to some embodiments, and FIG. 2 is a perspective view separately showing the pickup unit of FIG. 1.

Referring to FIG. 1, a conventional turntable-type probe pin laser bonding apparatus (100) may include a pickup unit (110), a dipping unit (120), a laser bonding unit (130), and a suction unit (140).

First, the pickup unit (110) is located in the center of the units (120, 130, 140) and transfers the probe pin (P) placed on the tray (T) while rotating 360 degrees on the horizontal line.

As shown in FIG. 1, the pickup unit (110) may rotate in a clockwise direction with a time difference of 90 degrees after picking up the probe pin (P) from the tray (T) disposed on the right side of the pickup unit (110) (based on FIG. 1).

In addition, the dipping unit (120) is located on the lower side of the pickup unit (110) (based on FIG. 1). The dipping unit (120) applies solder paste (see FIG. 5) to the probe pin (P) transferred by rotating 90 degrees clockwise by the pickup unit (110).

In addition, the laser bonding unit (130) is located on the left side of the pickup unit (110) (based on FIG. 1). The laser bonding unit (130) bonds the probe pin (P) to the probe card (S) by irradiating a laser beam to the solder paste of the probe pin (P) rotated 90 degrees clockwise from the dipping unit (120) by the pickup unit (110) and transferred.

In addition, the suction unit (140) is located above the pickup unit (110) (based on FIG. 1). The suction unit (140) removes the defective probe pin (P) by suction when a defect occurs among the probe pins (P) rotated 90 degrees clockwise from the laser bonding unit (130) by the pickup unit (110) and transferred.

That is, the pickup unit (110) picks and fixes the probe pin (P) from the tray (T) while rotating clockwise with a time difference by a set angle (e.g., 90 degrees). And then, the dipping process by the dipping unit (120), the laser bonding process by the laser bonding unit (130), and the suction process by the suction unit (140) are sequentially performed.

Hereinafter, by referring to FIG. 2, the configuration of the pickup unit will be described in detail as follows.

A pin gripper (112) in the shape of clamps for gripping and fixing the probe pin (P) is provided at the lowest end of the pickup unit (110).

In addition, a force control unit (114) for controlling the pin gripper (112) is provided at the upper end of the pin gripper (112) so that a constant grip force is applied to the probe pin (P).

In addition, while the pin gripper (112) and the force control unit (114) are mounted on the Z-axis driving unit (116), the pin gripper (112) and the force control unit (114) are also raised and lowered together by the vertical driving of the Z-axis driving unit (116).

In addition, the Z-axis driving unit (116) is provided on each side of the body unit (117) in the shape of a square box, and the body unit (117) has four side surfaces perpendicular to each other.

Accordingly, the pin gripper (112), the force control unit (114), and the Z-axis driving unit (116) are provided on each side of the body unit (117), respectively.

In addition, a rotation driving unit (118) is integrally coupled to the upper end of the body unit (117). The body unit (117) is rotated by, for example, 90 degrees by the rotational force of the rotation drive unit (118).

When the body unit (117) rotates, the pin gripper (112), the force control unit (114), and the Z-axis driving unit (116), which are fixedly coupled to each side of the body unit (117), are also rotated together with the body unit (117).

In addition, as the support frame (119) in the form of a gantry is coupled to the upper rotation shaft (118a) of the rotation drive unit (118), the pickup unit (110) comprising the rotation driving unit (118) is supported by the support frame (119) to be rotatable.

Therefore, the pickup unit (110) may pick up the provided probe pin (P) while being placed on the tray (T) and transfer it clockwise by a preset angle on the horizontal line.

However, to continuously perform the pickup, dipping, and laser bonding processes of probe pins that are getting smaller in micrometers day by day, as described above, the pickup unit of the conventional probe pin laser bonding apparatus has an improvement task in which the pin gripper moves linearly or rotationally in the X, Y, and Z-axis directions in micrometer units and must be very freely and precisely transferred.

### PRIOR ARTS

1. Korean Patent No. 1748583 (Registration Date: Jun. 16, 2017)

2. Korean Patent No. 1879376 (Registration Date: Jul. 11, 2018)

### DISCLOSURE OF INVENTION

### Problem to be Solved by the Invention

As the present invention was invented to solve the problems described above, the present invention provides a turntable-type probe pin laser bonding apparatus wherein a pin gripper mounted on four surfaces automatically laser-bonds a probe pin to a probe card while continuously rotating pin grippers in a turntable method. More particularly, the present invention provides a multi-axis gripper unit of a turntable type probe pin laser bonding apparatus that can continuously process the pickup, dipping, and laser bonding of probe pins while freely moving linearly or rotationally in multi-axis directions, for example, the X-axis, Y-axis, Xθ-axis, Yθ-axis, and the gripper axis, with high precision in micrometer units by being applied to the laser bonding unit.

### Means for Solving the Problem

To achieve the above purpose, according to some embodiments of the present invention, a multi-axis gripper unit of a turntable-type probe pin laser bonding apparatus comprising: a pickup unit that rotates 360 degrees on the horizontal line and transfers the probe pin placed on the tray after holding it with a pin gripper consisting of a pair of clamps; a dipping unit applies solder paste to the probe pin transferred by the pickup unit; and a laser bonding unit bonds the probe pins to the probe card by irradiating a laser beam onto the solder paste of the probe pins transferred from the dipping unit by the pickup unit, wherein, an X-axis and Y-axis linear transport module equipped at the end of the pickup unit to linearly transport the pin gripper in the X-axis or Y-axis direction; an Xθ-axis and Yθ-axis rotary transfer module equipped between the X-axis and Y-axis linear transfer module and the pin gripper to rotate the pin gripper in the Xθ-axis or Yθ-axis direction; a gripper axis linear transfer module equipped between the Xθ and Yθ axis rotary transfer module and the pin gripper to transport the pin gripper to narrow or widen the gap between the pin grippers so that the pin gripper can hold or release the probe pin.

In addition, according to some embodiments, the X-axis and Y-axis linear transfer modules, respectively, comprises a base frame; a piezoelectric actuator disposed on the base frame in the X-axis or Y-axis direction; and a slide frame that is linearly transferred in the X-axis and Y-axis directions by the motion of the piezoelectric actuator.

In addition, according to some embodiments, the piezoelectric actuator is equipped in a state of being inserted into the tube pin member integrally coupled to the slide frame so that the tube pin member and the slide frame are linearly transferred in the X-axis or Y-axis direction by the motion of the piezoelectric actuator.

In addition, according to some embodiments, a scale bar and an encoder PCB are further added to the base frame and the slide frame, respectively, to control the rotational feed amount in the X-axis or Y-axis direction of the slide frame.

In addition, according to some embodiments, the Xθ-axis and Yθ-axis rotation transfer modules, respectively, comprises a cover frame; a rotary block rotatably equipped between the cover frames; and a piezoelectric actuator that passes through the cover frame and rotates the rotary block in the Xθ axis or Yθ axis direction in a coupled state.

In addition, according to some embodiments, at least two or more plate springs are coupled to one side of the rotary axis of the rotary block, and a piezoelectric actuator is equipped in a state inserted between the plate springs. By the motion of the piezoelectric actuator, the plate spring and the rotary block are rotationally transferred in the Xθ axis or Yθ axis direction.

In addition, according to some embodiments, a scale bar and an encoder PCB are further added to the cover frame and the rotary block, respectively, to control the rotational feed amount in the Xθ axis or Yθ axis direction of the rotary block.

In addition, according to some embodiments, the gripper shaft linear transport module comprises a gripper base frame; a piezoelectric actuator fitted to the gripper base frame in the X-axis direction; a gripper slide frame that is linearly transferred in the X-axis direction by the motion of the piezoelectric actuator.

In addition, according to some embodiments, one of the left and right clamps of the pin gripper is fixed to the gripper base frame and the gripper slide frame. The gap between the left and right clamps of the pin gripper is narrowed or widened so that the pin gripper can hold or release the probe pin according to the linear movement of the gripper slide frame in the X-axis direction.

In addition, according to some embodiments, a scale bar and an encoder PCB are further added to the gripper base frame and the gripper slide frame, respectively, to control the amount of linear feed in the X-axis direction of the gripper slide frame.

### Effect of the Invention

As described above, in the present invention, the multi-axis gripper unit added to the turntable-type probe pin laser bonding apparatus freely moves linearly or rotationally in the multi-axis direction, for example, in the X-axis, Y-axis, Xθ-axis, Yθ-axis, and the gripper X-axis direction with high precision in micrometer units and pickup, dipping, and laser bonding of probe pins are possible. Accordingly, there is an effect that the efficiency and precision of the probe pin bonding process are greatly improved.

Accordingly, it is possible to prepare for the laser bonding process of the probe pin, which is being refined day by day in micrometer units. Also, there is an effect that can minimize the physical damage applied to very fine and sophisticated probe pins while continuously performing processes such as pickup, dipping, and laser bonding of the probe pins.

### BRIEF DESCRIPTION OF DRAWINGS

FIG. 1 is a plan view showing the configuration of a conventional turntable-type probe pin laser bonding apparatus according to some embodiments.

FIG. 2 is a perspective view showing the pickup unit of FIG. 1 separated.

FIG. 3 is a full perspective view of the multi-axis gripper unit of the turntable-type probe pin laser bonding apparatus of the present invention according to some embodiments.

FIG. 4 is an exploded perspective view showing the main part in an enlarged view of the X-axis and Y-axis linear transfer module of FIG. 3.

FIG. 5 is an exploded perspective view showing the main part in an enlarged view of the Yθ axis rotary transfer module of FIG. 3.

FIG. 6 is an exploded perspective view showing the main part in an enlarged Xθ axis rotary transfer module of FIG. 3.

FIG. 7 is an exploded perspective view showing the main part of an enlarged gripper shaft linear transfer module of FIG. 3.

### MODE(S) FOR CARRYING OUT THE INVENTION

The terminology herein describes particular embodiments only and is not intended to be limiting. As used herein, the singular forms “a, ” “an, ” and “the” are intended to include the plural forms, including “at least one, ” unless the content clearly indicates otherwise. It will be further understood that the terms “comprises, ” “comprising, ” “includes, ” and/or “including, ” when used in this specification, specify the presence of stated features, integers, steps, operations, elements, and/or components, but do not preclude the presence or addition of one or more other features, integers, steps, operations, elements, components, and/or groups thereof.

Unless otherwise defined in this specification, all terms used herein (including technical and scientific terms) have the same meaning as commonly understood by those skilled in the art.

It will be further understood that terms, such as those defined in commonly used dictionaries, should be interpreted as having a meaning that is consistent with their meaning in the context of the relevant art and will not be interpreted in an ideal or excessively formal sense unless clearly defined in the present specification.

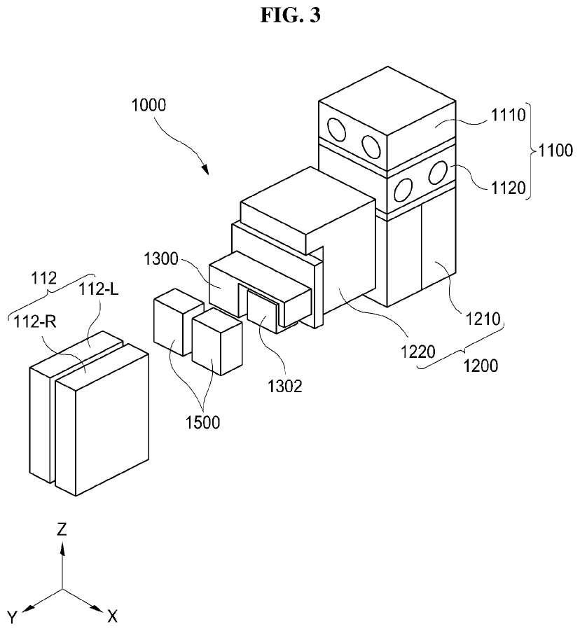

Hereinafter, the multi-axis gripper unit of the turntable-type probe pin laser bonding apparatus, according to some embodiments of the present invention, will be described in detail with reference to the accompanying FIGS. 3 to 7 as follows.

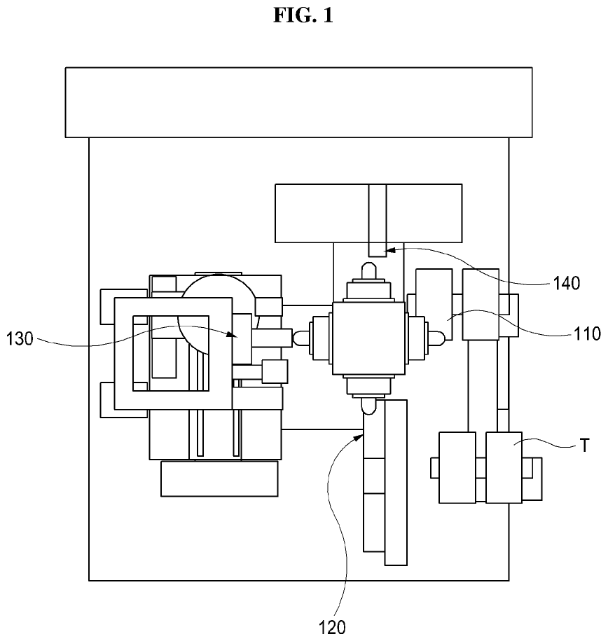

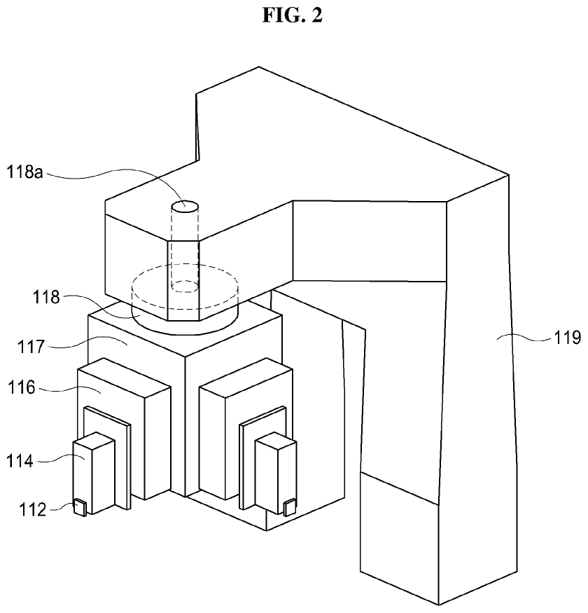

As described above with reference to FIGS. 1 and 2, a multi-axis gripper unit of a turntable-type probe pin laser bonding apparatus of the present invention comprising: a pickup unit that rotates 360 degrees on the horizontal line and transfers the probe pin placed on the tray after holding it with a pin gripper consisting of a pair of clamps; a dipping unit applies solder paste to the probe pin transferred by the pickup unit; and a laser bonding unit bonds the probe pins to the probe card by irradiating a laser beam onto the solder paste of the probe pins transferred from the dipping unit by the pickup unit.

FIG. 3 is a full perspective view of the multi-axis gripper unit of the turntable-type probe pin laser bonding apparatus of the present invention according to some embodiments.

Referring to FIG. 3, the multi-axis gripper unit of the present invention may be configured as a 5-axis module according to some embodiments.

First, as the first and second components of the 5-axis module, an X-axis and Y-axis linear transport module (1100: 1110, 1120) is equipped to linearly transport the pin gripper (112) in the X-axis or Y-axis direction at the end of the pickup unit (110) of the turntable-type probe pin laser bonding apparatus.

In addition, as the third and fourth components of the present invention, an Xθ-axis and Yθ-axis rotation transfer module (1200: 1210, 1220) is equipped to rotate the pin gripper (112) in the Xθ-axis or Yθ-axis direction between the X-axis and Y-axis linear transfer module (1100) and the pin gripper (112).

In addition, as the fifth component of the present invention, a gripper shaft linear transfer module (1300) is equipped to narrow or widen the gap between the pin grippers (112) so that the pin gripper (112) can hold or release a probe pin (not shown) between the Xθ axis and Yθ axis rotation transfer module (1200) and the pin gripper (112).

In addition, as shown in FIG. 3, a separate bracket (1500) may be further equipped for screwing and fixing the pin gripper (112) to the gripper shaft linear transfer module (1300)

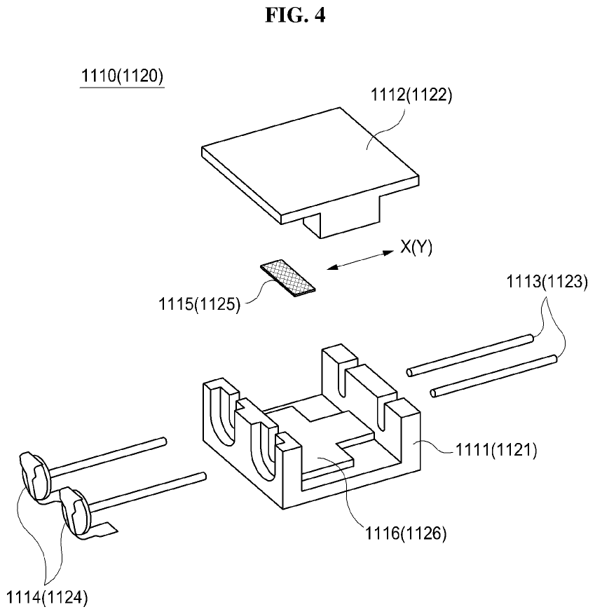

FIG. 4 is an exploded perspective view showing the main part in an enlarged view of the X-axis and Y-axis linear transfer module of FIG. 3.

Referring to FIG. 4, the X-axis and Y-axis linear transfer modules (1110) (1120) respectively comprise a ‘ [symbol] ’ shaped base frame (1111)(1121), the piezoelectric actuators (1114) (1124) positioned in the X-axis or Y-axis direction on the base frame and the slide frames (1112)(1122) are linearly transported in the X-axis or Y-axis direction by a motion such as vibration selectively applied as electrical energy is added to the piezoelectric actuators (1114) (1124).

The piezoelectric actuator may be, for example, a miniature piezoelectric actuator using a piezoelectric ceramic. The miniature piezoelectric actuator applies an electric field to the piezoelectric ceramic polarized in one direction so that a contraction or expansion motion occurs in the piezoelectric ceramic according to the polarization direction and the applied electric field direction. The moving body moves linearly by transmitting this bending vibration to the moving shaft.

In addition, the piezoelectric actuators (1114)(1124) are equipped in a state of being inserted into the tube pin members (1113)(1123) integrally coupled to the slide frames (1112)(1122) so that electric energy is added to the piezoelectric actuators (1112)(1122), a fine motion such as vibration is generated. And by the motion of the piezoelectric actuators (1112)(1122), the tube pin members (1113)(1123) and the slide frames (1112)(1122) are linearly transported very precisely in the X-axis or Y-axis direction.

In addition, as scale bars (1115)(1125) and encoder PCBs (1116)(1126) are further added to the base frames (1111)(1121) and the slide frames (1112)(1122), respectively, the amount of linear feed in the X-axis or Y-axis direction of the slide frames (1112)(1122) is precisely controlled.

Accordingly, by the configuration of the piezoelectric actuators (1112)(1122), the scale bars (1115)(1125), and the encoder PCBs (1116)(1126), the X-axis and Y-axis linear transfer modules (1110)(1120) linearly transport the slide frames (1112)(1122) very precisely in micrometer units.

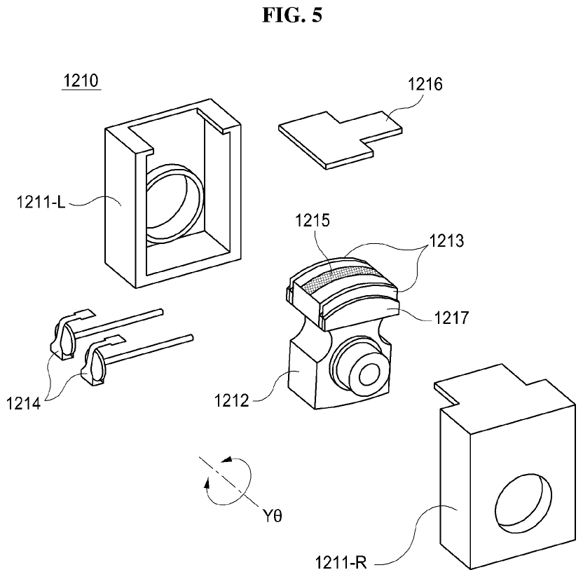

FIG. 5 is an exploded perspective view showing the main part in an enlarged view of the Yθ axis rotary transfer module of FIG. 3.

Referring to FIG. 5, the Yθ axis rotation transfer module (1210) respectively comprises a pair of left and right cover frames (1211-L, 1211-R), a rotary block (1212) rotatably equipped between the cover frames (1211-L, 1211-R), a piezoelectric actuator (1214) that passes through the cover frames (1211-L, 1211-R) and rotates the rotary block (1212) in the Yθ axis direction in a coupled state.

As shown in FIG. 5, the rotary block (1212) is formed as a rotating bundle having a circular arc-shaped curved surface on the part of the rotation shaft according to some embodiments, and a pair of plate springs (1213) is coupled to the left and right sides of the round curved surface, respectively.

At this time, the plate spring (1213) is fixedly coupled to the rotary block (1212) in a state of being spaced apart from each other by a predetermined interval by at least one or more spacers (1217).

Subsequently, as the piezoelectric actuator (1214) is positioned in a state inserted between the pair of plate springs (1213), the plate spring (1213) and the rotary block (1212) are precisely rotationally transferred in the Yθ axis direction by minute motions such as vibration of the piezoelectric actuator (1214).

In addition, a scale bar (1215) and an encoder PCB (1216) are further added to the left and right cover frames (1211-L, 1211-R) and the rotary block (1212), respectively, so that the rotational feed amount in the Xθ-axis or Yθ-axis direction of the rotary block (1212) is precisely controlled.

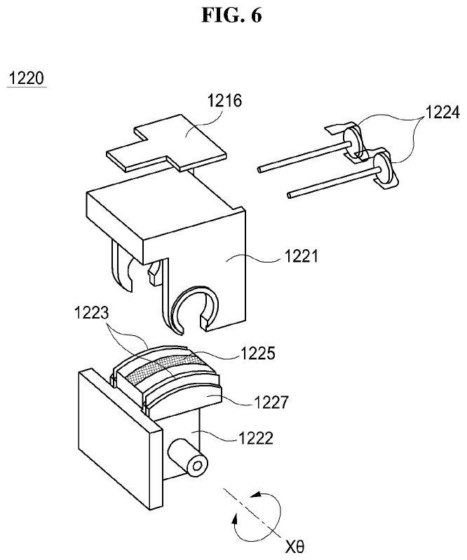

FIG. 6 is an exploded perspective view showing the main part in an enlarged Xθ axis rotary transfer module of FIG. 3.

FIG. 6 shows an embodiment of an Xθ-axis rotary transfer module. Unlike the configuration of the cover frame of FIG. 5, the cover frame (1221) of the Xθ-axis rotary transfer module of FIG. 6 may be integrally formed. The remaining components (1222, 1223, 1224, 1225, 1226, and 1227) may be applied in the same manner as the configuration of FIG. 5. Hereinafter, a description of the same configuration as that of FIG. 5 will be omitted.

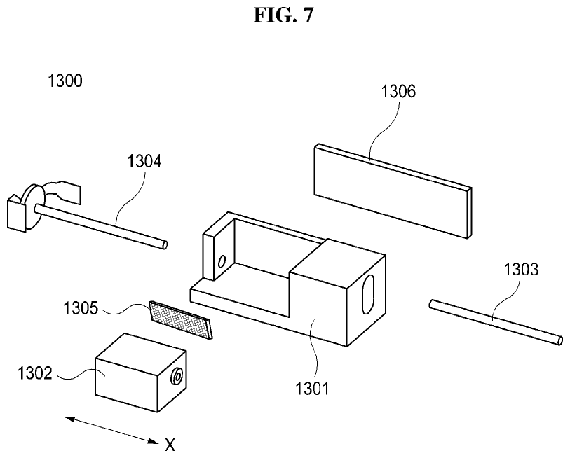

FIG. 7 is an exploded perspective view showing the main part of an enlarged gripper shaft linear transfer module of FIG. 3.

Referring to FIG. 7, the gripper shaft linear transfer module (1300) comprises a gripper base frame (1301), a piezoelectric actuator (1303) fitted to the gripper base frame (1301) in the X-axis direction, a gripper slide frame (1302) linearly transported in the X-axis direction by the motion of the piezoelectric actuator (1303).

The piezoelectric actuator (1304) is inserted into the tube pin member (1303) coupled to the gripper slide frame (1302). When a minute motion such as vibration is generated in the piezoelectric actuator (1304), the tube pin member (1303) and the gripper slide frame (1302) are precisely linearly transferred in the X-axis direction on a micrometer scale.

At this time, as shown in FIG. 3, the left and right clamps (112-L, 112-R) of the pin gripper (112) are respectively fixed to the gripper base frame (1301) and the gripper slide frame (1302). The gap between the left and right clamps (112-L, 112-R) of the pin gripper (112) is operated to narrow or widen so that the pin gripper (112) can hold or release a probe pin (not shown) according to the linear movement of the gripper slide frame (1302) in the X-axis direction.

In addition, a scale bar (1305) and an encoder PCB (1306) are further added to the gripper base frame (1301) and the gripper slide frame (1302), respectively, so that the linear feed amount in the X-axis direction of the gripper slide frame (1302) is precisely controlled.

Therefore, the present invention is not limited only by the embodiments described above. It is possible to create the same effect even if the apparatus's detailed configuration or number and layout structure are changed, or the detailed steps are changed and added. It is possible to add, delete, and modify various configurations within the scope of the technical spirit of the present invention by those of ordinary skill in the art.

### DESCRIPTION OF THE NUMERALS

112 (112-L, 112-R): pin gripper(left. Right clamps)
1000: (the present invention) multi-axis gripper unit
1100: an X-axis and Y-axis linear transport module
1110: X-axis linear transport module
1120: Y-axis linear transport module
1111, 1121: base frame
1112, 1122: slide frame
1113, 1123: tube pin member
1114, 1124: piezoelectric actuator
1115, 1125: scale bar
1116, 1126: encoder PCB
1200: Xθ-axis and Yθ-axis rotation transfer module
1210: Yθ-axis rotation transfer module
1220: Xθ-axis rotation transfer module
1211: cover frame
1212, 1222: rotary block
1213, 1223: plate spring
1214, 1224: piezoelectric actuator
1215, 1225: scale bar
1216, 1226: encoder PCB
1217, 1227: spacer
1300: gripper shaft linear transfer module
1301: gripper base frame
1302: gripper slide frame
1303: tube pin member
1304: piezoelectric actuator
1305: scale bar
1306: encoder PCB

1. A multi-axis gripper unit of a turntable-type probe pin laser bonding apparatus comprising:
a pickup unit that rotates 360 degrees on the horizontal line and transfers the probe pin placed on the tray after holding it with a pin gripper consisting of a pair of clamps;
a dipping unit applies solder paste to the probe pin transferred by the pickup unit; and
a laser bonding unit bonds the probe pins to the probe card by irradiating a laser beam onto the solder paste of the probe pins transferred from the dipping unit by the pickup unit, wherein,
an X-axis and Y-axis linear transport module equipped at the end of the pickup unit to linearly transport the pin gripper in the X-axis or Y-axis direction;
an Xθ-axis and Yθ-axis rotary transfer module equipped between the X-axis and Y-axis linear transfer module and the pin gripper to rotate the pin gripper in the Xθ-axis or Yθ-axis direction;
a gripper axis linear transfer module equipped between the Xθ and Yθ axis rotary transfer module and the pin gripper to transport the pin gripper to narrow or widen the gap between the pin grippers so that the pin gripper can hold or release the probe pin.

2. The multi-axis gripper unit of a turntable-type probe pin laser bonding apparatus of claim 1,
wherein the X-axis and Y-axis linear transfer modules, respectively, comprise:
a base frame;
a piezoelectric actuator disposed on the base frame in the X-axis or Y-axis direction; and
a slide frame that is linearly transferred in the X-axis and Y-axis directions by the motion of the piezoelectric actuator.

3. The multi-axis gripper unit of a turntable-type probe pin laser bonding apparatus of claim 2,
wherein the piezoelectric actuator is equipped to be inserted into the tube pin member, which is integrally coupled to the slide frame so that the tube pin member and the slide frame are linearly transferred in the X-axis or Y-axis direction by the motion of the piezoelectric actuator.

4. The multi-axis gripper unit of a turntable-type probe pin laser bonding apparatus of claim 2,
wherein the scale bar and the encoder PCB are further added to the base frame and the slide frame, respectively, to control the rotational feed amount in the X-axis or Y-axis direction of the slide frame.

5. The multi-axis gripper unit of a turntable-type probe pin laser bonding apparatus of claim 2,
wherein the Xθ-axis and Yθ-axis rotary transfer modules, respectively, comprise:
a cover frame;
a rotary block rotatably equipped between the cover frames; and
a piezoelectric actuator that passes through the cover frame and rotates the rotary block in the Xθ axis or Yθ axis direction in a coupled state.

6. The multi-axis gripper unit of a turntable-type probe pin laser bonding apparatus of claim 5,
wherein at least two or more plate springs are coupled to one side of the rotary axis of the rotary block, and a piezoelectric actuator is equipped in a state inserted between the plate springs, and by the motion of the piezoelectric actuator, the plate spring and the rotary block are rotationally transferred in the Xθ axis or Yθ axis direction.

7. The multi-axis gripper unit of a turntable-type probe pin laser bonding apparatus of claim 5,
wherein the scale bar and the encoder PCB are further added to the cover frame and the rotary block, respectively, to control the rotational feed amount in the Xθ axis or Yθ axis direction of the rotary block.

8. The multi-axis gripper unit of a turntable-type probe pin laser bonding apparatus of claim 1,
the gripper shaft linear transport module comprises;
a gripper base frame;
a piezoelectric actuator fitted to the gripper base frame in the X-axis direction; and
a gripper slide frame that is linearly transferred in the X-axis direction by the motion of the piezoelectric actuator.

9. The multi-axis gripper unit of a turntable-type probe pin laser bonding apparatus of claim 8,
wherein one of the left and right clamps of the pin gripper is fixed to the gripper base frame and the gripper slide frame, respectively, and the gap between the left and right clamps of the pin gripper is narrowed or widened so that the pin gripper can hold or release the probe pin according to the linear movement of the gripper slide frame in the X-axis direction.

10. The multi-axis gripper unit of a turntable-type probe pin laser bonding apparatus of claim 8,
wherein the scale bar and the encoder PCB are further added to the base frame and the slide frame, respectively, to control the rotational feed amount in the X-axis or Y-axis direction of the slide frame.
